(19) United States
(12) Patent Application Publication
(10) Pub. No.: US 2007/0268657 A1
(43) Pub. Date: Nov. 22, 2007

(54) Rack-mountable device

(76) Inventors: Keith J. Kuehn, Houston, TX (US); Belgie B. McClelland, Houston, TX (US); George R. Daniels, Houston, TX (US); Sebastian M. J. Petry, Houston, TX (US); Chris F. Felcman, Houston, TX (US); Gary S. Landrum, Houston, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/438,555

(22) Filed: May 22, 2006

(51) Int. Cl. H05K 5/00

(52) U.S. Cl. 361/679

(57) ABSTRACT

Systems, methods, and media associated with a rack-mountable device are described. One exemplary system embodiment includes a display having a corner to diagonally opposite corner dimension of at least seventeen inches, a pointing apparatus having at least three buttons, a communication access port positioned on the front of the device, and an identification light positioned on the front of the device. In one example, the device will fold open and shut. In one example, the device will fit into a 1 U (1.75 inch) rack space when the device is folded shut and will have a QWERTY keyboard having a horizontal dimension of at least fourteen inches.

### BACKGROUND

Rack-mounted systems continue to grow in usefulness, density, and popularity. Conventionally, computers, servers, KVMs (keyboard, video, mouse) and other equipment housed in a standard (e.g. 19″ horizontal) 1 U (e.g., 1.75″ vertical) space have made concessions to these small horizontal and vertical dimensions. These concessions may have created sub-optimal experiences for some rack-mounted system users. Additionally, conventional computers, servers, KVMs, and other equipment housed in a standard 1 U space may not have accounted for either the “front-oriented” nature or the density of a rack-mounted environment.

By way of illustration, conventional devices may have included communication access ports (e.g., USB port) that were located on the back of the device. Since a user typically has easier access to the front of a rack-mounted device this may have made it difficult to (dis)connect cables to this access port and/or to even visually inspect connections associated with the access port. By way of further illustration, small difficult to use keyboards, small difficult to read monitors, and small difficult to use limited pointing devices (e.g., trackballs) may have been squeezed into the minimally available space. Additionally, once mounted in a 1 U space, one device may have been pretty much indistinguishable from another device. Thus, it may have been difficult to identify a device with which a user wanted to interact (e.g., remove, replace, monitor, (dis)connect cables). Thus, conventional rack-mounted devices may have provided certain advantages, but may also have produced a sub-optimal experience.

### BRIEF DESCRIPTION OF THE DRAWINGS

The accompanying drawings, which are incorporated in and constitute a part of the specification, illustrate various example systems, and methods. It will be appreciated that the illustrated element boundaries (e.g., boxes, groups of boxes, or other shapes) in the figures represent one example of the boundaries. One of ordinary skill in the art will appreciate that in some cases one element may be designed as multiple elements, that multiple elements may be designed as one element, that an element shown as an internal component of another element may be implemented as an external component and vice versa, and so on. Furthermore, elements may not be drawn to scale.

FIG. 1 illustrates an example rack-mountable device.

FIG. 2 illustrates front, top, and side views of an example rack-mountable device.

FIG. 3 illustrates an example rack-mountable device in a folded open configuration.

FIG. 4 illustrates an example rack-mountable device in a folded shut configuration.

FIG. 5 illustrates an example method associated with controlling a light associated with a rack-mountable device.

FIG. 6 illustrates an example rack-mountable device.

FIG. 7 illustrates example devices in various positions in a rack.

### DETAILED DESCRIPTION

An example rack-mountable device may include a larger (e.g., 17″) more useful monitor, an integrated full-sized pointing unit (e.g., touchpad) with a full complement of buttons (e.g., 3), a communication access port(s) (e.g., USB port) located on and/or accessible to the front of the device, and a light(s) located on and/or accessible to the front of the device. The light(s) may facilitate locating and/or identifying a device in a set of devices located in a rack. In one example, the rack-mountable device may fold (e.g., like a laptop computer) to fit into a 1 U space in a 19 inch wide rack. In one example, the rack-mountable device may be slideable in a 1 U space and may be able to fold open while still attached to a rack. Thus, the rack-mountable device may be unfolded and used without undoing connections (e.g., communications cables, cooling hoses). In one example, the rack-mountable device may include a QWERTY keyboard having a horizontal dimension of at least fourteen inches measured from the center of the leftmost key to the center of the rightmost key.

The following includes definitions of selected terms employed herein. The definitions include various examples and/or forms of components that fall within the scope of a term and that may be used for implementation. The examples are not intended to be limiting. Both singular and plural forms of terms may be within the definitions.

“Computer-readable medium”, as used herein, refers to a medium that participates in directly or indirectly providing signals, instructions and/or data that can be read by a computer. A computer-readable medium may take forms, including, but not limited to, non-volatile media (e.g., optical disk, magnetic disk), volatile media (e.g., semiconductor memory, dynamic memory), and transmission media (e.g., coaxial cable, copper wire, fiber optic cable, electromagnetic radiation). Common forms of computer-readable mediums include floppy disks, hard disks, magnetic tapes, CD-ROMs, RAMs, ROMs, carrier waves/pulses, and so on. Signals used to propagate instructions or other software over a network, like the Internet, can be considered a “computer-readable medium.”

“KVM”, as used herein, refers to a hardware device referred to as a keyboard, video, mouse unit. A KVM has a keyboard, a video monitor, and a pointing device (e.g., mouse).

“Rack” as used herein refers to a frame, usually metal, designed to hold computer and other hardware devices (e.g., KVM). A rack may be positioned in a cabinet.

“Rack slot” and “rack space” as used herein refer to a portion of a rack, the portion being configured to receive a computer or other hardware device (e.g., KVM). A rack slot may be a shelf in a rack.

“1 U” as used herein refers to a measurement of vertical usable space. U is a standard unit of measure for designating the vertical usable space (e.g., height) of racks. 1 U may refer to the space between shelves on a rack. 1 U is equal to 1.75 inches. A rack designated as 10 U has 10 rack spaces or rack slots for equipment (e.g., computers, KVMs) and has 17.5 (10×1.75) inches of vertical usable space.

“Signal”, as used herein, includes but is not limited to, electrical signals, optical signals, analog signals, digital signals, data, computer instructions, processor instructions, messages, a bit, a bit stream, or other means that can be received, transmitted and/or detected.

Some portions of the detailed descriptions that follow are presented in terms of algorithm descriptions and representations of operations on electrical and/or magnetic signals capable of being stored, transferred, combined, compared, and otherwise manipulated in hardware. These algorithmic descriptions and representations are used by those skilled in the art to convey the substance of their work to others. An algorithm is here, and generally, conceived to be a sequence of operations that produce a result. The operations may include physical manipulations of physical quantities.

It has proven convenient at times, principally for reasons of common usage, to refer to these electrical and/or magnetic signals as bits, values, elements, symbols, characters, terms, numbers, and so on. These and similar terms are associated with appropriate physical quantities and are merely convenient labels applied to these quantities. Unless specifically stated otherwise, it is appreciated that throughout the description, terms including processing, computing, calculating, determining, displaying, automatically performing an action, and so on, refer to actions and processes of a computer system, logic, processor, or similar electronic device that manipulates and transforms data represented as physical (electric, electronic, magnetic) quantities.

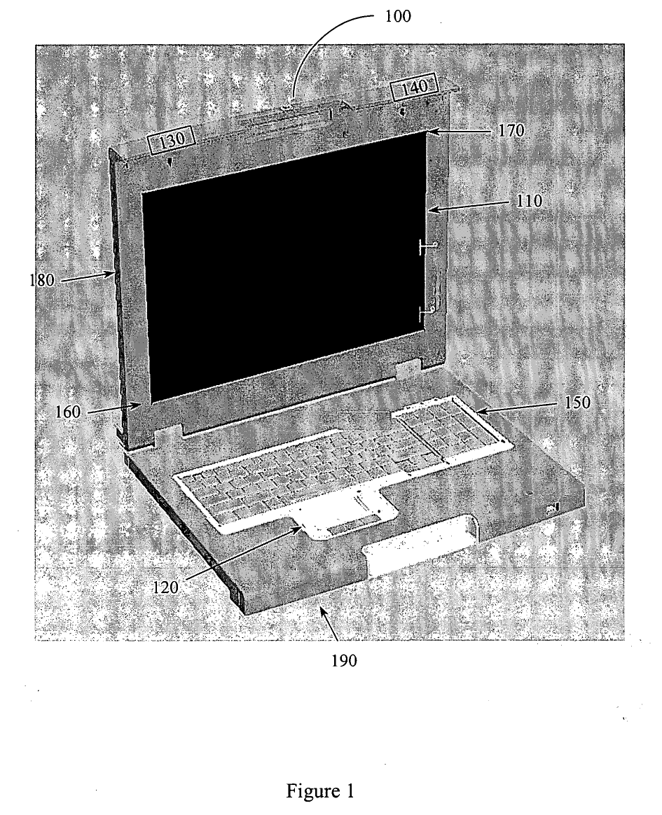

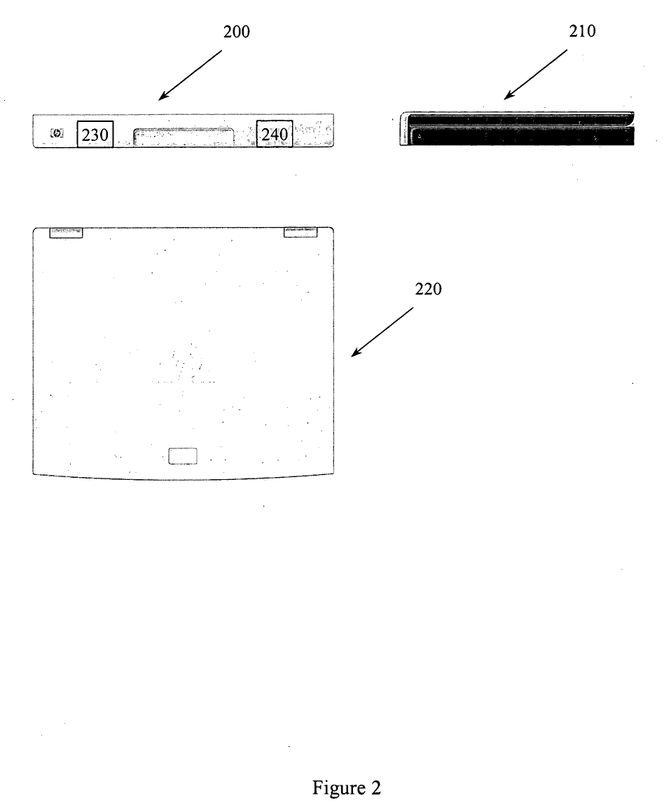

FIG. 1 illustrates an example rack-mountable device 100. Rack-mountable device 100 may share some characteristics of a laptop computer or KVM. For example, rack-mountable device 100 is foldable and generally considered to be thin (e.g., <2 inches when folded shut). In one example, rack-mountable device 100 is configured to fold open and fold shut and, when folded shut, to fit into a nineteen inch wide, 1 U rack space. While a nineteen inch 1 U space is described, it is to be appreciated that in other examples device 100 may be positioned in racks having other dimensions. Device 100 is configured so that when folded shut and positioned in a rack the front of rack-mountable device 100 will be visible. An example front view can be seen in front view 200 (FIG. 2).

Device 100 may include a display 110 that has a corner to diagonally opposite corner dimension of at least seventeen inches. For example, from corner 160 to corner 170 may be at least seventeen inches. The display 110 may be, for example, a liquid crystal display (LCD), a video display, and so on.

Device 100 may also include a pointing apparatus 120 having at least three buttons. The three buttons may facilitate, for example, “left clicking”, “right clicking”, and so on. In one example, the pointing apparatus 120 may be a touch pad. In other examples, the pointing apparatus 120 may be a track ball or other pointing apparatus.

Device 100 may also include a communication access port 130 that is positioned on the front of device 100. While FIG. 1 illustrates communication access port 130 being positioned on portion 180 that folds down to cover portion 190, in other examples access port 130 may be positioned on portion 190. In another example, communication access port 130 may be configured to be accessible from the front of device 100 when device 100 is located in a rack. Communication access port 130 may be, for example, a universal serial bus (USB) port, a local area connection port, a wide area connection port, and so on.

Device 100 may also include an identification light 140 that is positioned on the front of device 100. Once again, while light 140 is illustrated on a portion 180 of device 100 that folds and covers portion 190, in other examples light 140 may be located on portion 190. In one example, light 140 may not be positioned on the front of device 100 but may be positioned to be visible from the front of device 100 when device 100 is located in a rack. The identification light 140 may be selectively controllable to take on different states. For example, when device 100 is folded shut, identification light 140 may take an “on” (e.g., illuminated) state and when device 100 is open identification light 140 may take an “off” (e.g., not illuminated) state. The different states available for identification light 140 may facilitate locating the device 100 when it is folded shut and positioned in a rack. In other examples, the identification light 140 may be controllable to take on a certain brightness, to take on a certain color, to blink, to blink at a certain rate, to display repeating patterns, and so on.

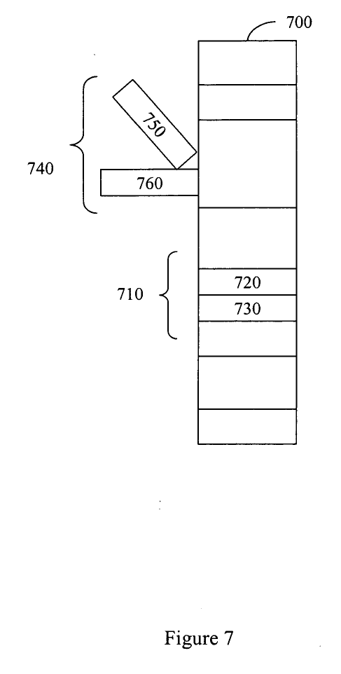

As described above, device 100 may be foldable. In one example, device 100 may be configured to be folded open when still attached to a rack. For example, device 100 may slide forward on a shelf in a rack. When device 100 has reached the front of the shelf but before device 100 is detached from the shelf and/or the rack, device 100 may be configured to be held by the rack and still be folded open. A side view of these positions is provided in FIG. 7. This may facilitate, for example, maintaining connections with communication cables, liquid cooling hoses, electrical cables, and so on. To facilitate folding, device 100 may have two portions that are attached to each other with a hinge(s). This configuration will be familiar to users of laptop computers. The hinge(s) may be positioned at and/or near the rear of the two portions.

Device 100 may also include a keyboard 150. In one example, the keyboard 150 may be a QWERTY keyboard. In one example, the keyboard 150 may have a horizontal dimension of at least fourteen inches measured from the center of the leftmost key to the center of the rightmost key. While a QWERTY keyboard and a horizontal dimension of fourteen inches are described, it is to be appreciated that in other examples different keyboards having different dimensions (e.g., 14.25″) may be employed.

FIG. 2 illustrates three views of an example rack-mountable device that is folded shut. View 200 is a front view that shows an access port 230 and an identification light 240. View 210 is a side view that shows a foldable portion on top of a fixed portion. View 220 is a top view. While access port 230 and identification light 240 are illustrated on the front of the rack-mountable device, it is to be appreciated that in other examples access port 230 and/or identification light 240 may be positioned to be accessible and/or viewable from the front of the computer when it is mounted in a rack. Thus, in some examples access port 230 and/or identification light 240 may not be physically located on the front of the rack-mountable device.

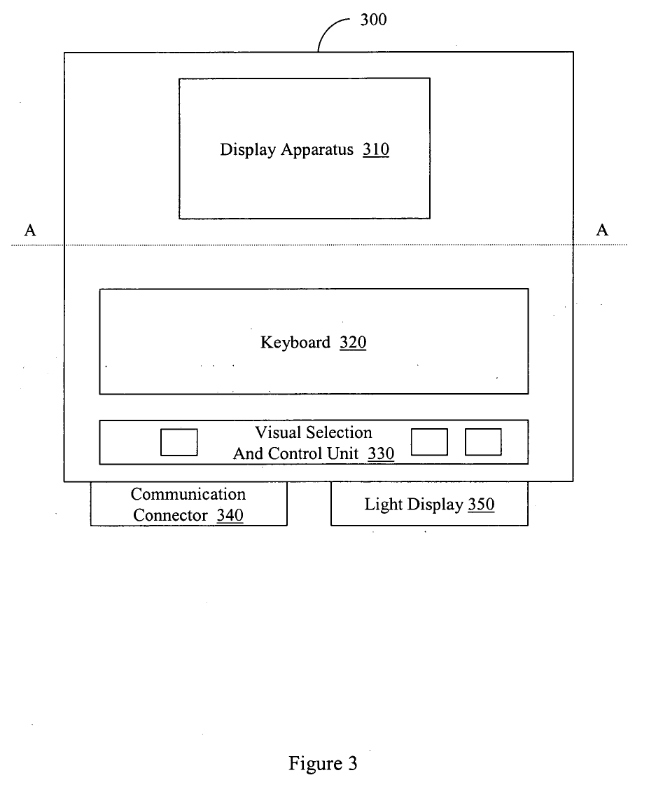

FIG. 3 illustrates a rack-mountable device 300. Device 300 includes a display apparatus 310 having a corner to diagonally opposite corner dimension larger than fifteen inches. For example, display apparatus 310 may have a dimension of seventeen inches. The display apparatus 310 may be, for example, an LCD or other display device. Device 300 may be, for example, a “dumb” terminal. Thus, device 300 may be of a class of devices commonly referred to as KVM (keyboard, video, monitor) devices.

Device 300 includes a keyboard 320. In one example, the keyboard 320 may have a horizontal dimension larger than twelve inches. In another example, the keyboard 320 may have a horizontal dimension of at least fourteen inches. The keyboard 320 may be, for example a QWERTY keyboard.

Device 300 includes a visual selection and control unit 330 that is configured with more than two buttons. Visual selection and control unit 330 may be, for example, a touch pad, a track ball, a mouse, and so on. Visual selection and control unit 330 may have three buttons.

Device 300 includes a communication connector 340 that is positioned to be accessible from the front of the device 300 when the device 300 is located in a rack. Thus, in one example, the communication connector 340 may be positioned on the front of device 300 while in another example the communication connector 340 may be positioned on the top of device 300 but near the front edge of device 300. The communication connector 340 may be, for example, a USB port, a LAN port, and so on.

Device 300 may also include a light display 350 that is positioned to produce a light that is viewable from the front of the device 300 when the device 300 is located in a rack. Thus, in one example the light display 350 may be located on the front of the device 300 while in another example the light display 350 may be located on the bottom, top, or side of device 300 but near the front of the device 300. Light display 350 is configured to be selectively controllable to facilitate locating the device 300 when the device 300 is positioned in a rack. For example, light display 350 may be configured to display a certain light pattern, to display a certain light color, to display a certain blinking pattern, to display a message, and so on. In one example light display 350 may simply take on two states, an “on” state when the device 300 is folded shut and an “off” state when the device 300 is folded open.

Device 300 is configured to fit into a space (e.g., shelf) in a rack. In one example the space in the rack may be a nineteen inch wide by 1.75 inch (1 U) high space. The device 300 is foldable which facilitates sliding device 300 into in a rack space. Device 300 may fold, for example, along axis A-A. In one example, device 300 may be moved forward in a rack space and folded open without being detached from the rack in which it is positioned. To facilitate folding, device 300 may have two parts that are hinged together along axis A-A.

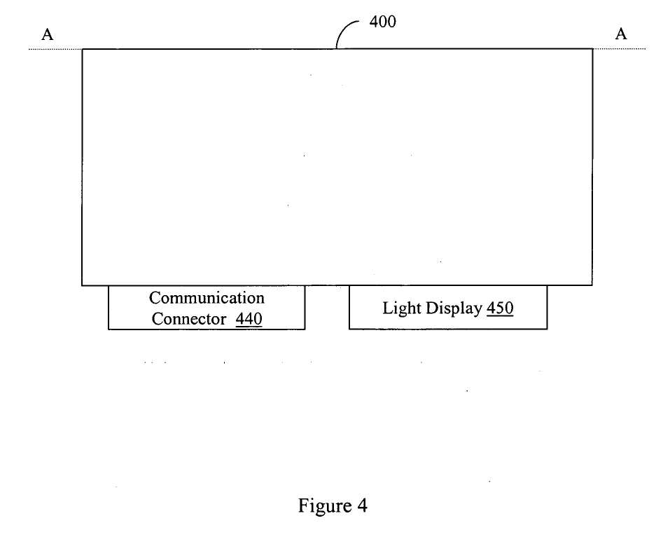

FIG. 4 illustrates a rack-mountable device 400 that is folded shut. Device 400 may have been folded shut, for example, along axis A-A. While folded shut, a communication connector 440 may be accessible from the front of device 400. Similarly, a light display 450 may be visible from the front of device 400. Thus, the communication connector 440 may be accessible from the front when the device 400 is located in a rack. Similarly, the light display 450 may produce light that is visible from the front of device 400 when device 400 is positioned in a rack.

An example method may be better appreciated with reference to a flow diagram. While for purposes of simplicity of explanation, the illustrated method is shown and described as a series of blocks, it is to be appreciated that the method is not limited by the order of the blocks, as some blocks can occur in different orders and/or concurrently with other blocks from that shown and described. Moreover, less than all the illustrated blocks may be required to implement an example method. In some examples, blocks may be combined, separated into multiple components, may employ additional, not illustrated blocks, and so on. In some examples, blocks may be implemented in logic. In other examples, processing blocks may represent functions and/or actions performed by functionally equivalent circuits (e.g., an analog circuit, a digital signal processor circuit, an application specific integrated circuit (ASIC)), or other logic device. Blocks may represent executable instructions that cause a computer, processor, and/or logic device to respond, to perform an action(s), to change states, and/or to make decisions. While the figures illustrate various actions occurring in serial, it is to be appreciated that in some examples various actions could occur concurrently, substantially in parallel, and/or at substantially different points in time.

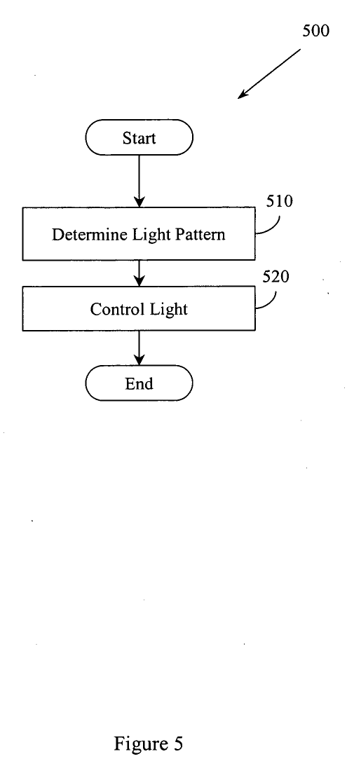

FIG. 5 illustrates a method 500 that may be performed to control a light on a rack-mountable device. For example, a light associated with device 100 (FIG. 1) or device 300 (FIG. 3) may be controlled by method 500. In one example, method 500 may control an identification light 140 (FIG. 1) while in another example method 500 may control a light display 350 (FIG. 3). Thus, method 500 may be tasked with controlling a light positioned to be viewable from in front of a rack-mountable device while the rack-mountable device is positioned in a rack. The light may be controllable to display a desired signal. That desired signal may facilitate locating the rack-mountable device while the rack-mountable device is positioned in a rack.

Method 500 may include, at 510, determining a light pattern to be displayed. Characteristics of the light pattern may include, for example, a brightness (e.g., on, off, dim, bright), a color (e.g., red, green), a blink rate, a message, and so on. In one example, the characteristics of the light pattern may simply include an “on” (e.g., illuminated) state and an “off” (e.g., not illuminated) state. Method 500 may also include, at 520, controlling the light to display the light pattern. In one example, the light pattern may include a repeating set of signals. The repeating set of signals may indicate, for example, an error condition (e.g., overheating), a status condition (e.g., sleep mode), a device location, and so on.

While FIG. 5 illustrates actions occurring in serial, it is to be appreciated that in one example actions illustrated in FIG. 5 could occur substantially in parallel. By way of illustration, a first process could determine a light pattern to display and a second process could control the light to display the pattern. While two processes are described, it is to be appreciated that a greater and/or lesser number of processes could be employed and that lightweight processes, regular processes, threads, and other approaches could be employed.

In one example, method 500 is implemented as processor executable instructions and/or operations stored on a computer-readable medium. Thus, in one example, a computer-readable medium may store processor executable instructions operable to perform a method that includes controlling a light positioned to be viewable from in front of a rack-mountable device while the rack-mountable device is positioned in a rack. The light may be controllable to display a desired signal. The desired signal may facilitate locating the rack-mountable device while it is positioned in a rack. For example, the light may display a unique pattern, may flash at a certain rate, may take on a certain color, and so on. While the above method is described being stored on a computer-readable medium, it is to be appreciated that other example methods described herein may also be stored on a computer-readable medium.

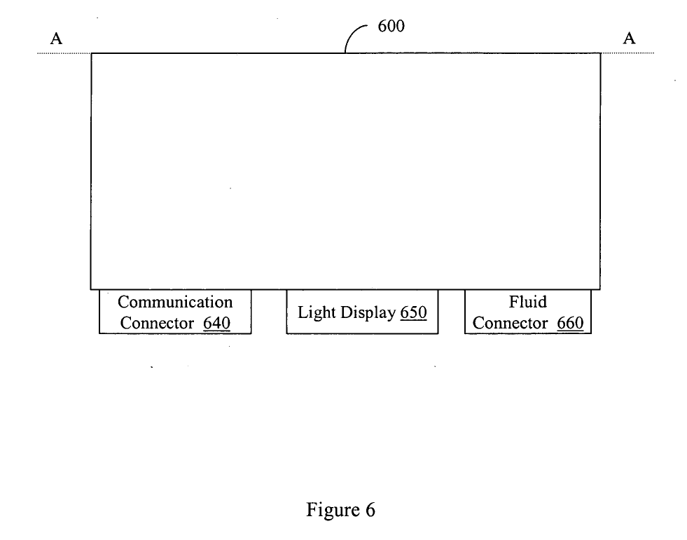

FIG. 6 illustrates an example rack-mountable device 600 that includes a fluid connector 660. Rack-mountable device 600 may include some elements similar to those described in FIG. 4. For example, device 600 may include a communication connector 640 and a light display 650.

Additionally, device 600 may include a fluid connector 660 that facilitates liquid cooling the device 600. Cooled liquid may be supplied, for example, by a rack in which the device 600 is located. Placing the connector 660 on the front of the device 600 may facilitate connecting and disconnecting the device 600 from liquid cooling without removing the device 600 from a rack.

FIG. 7 illustrates a side view of a rack 700 in which a first rack-mountable device 710 is inserted. The device 710 is in a folded shut configuration and is positioned in a “slided in” configuration. Since the device 710 is folded shut, top portion 720 is folded down onto bottom portion 730.

FIG. 7 also illustrates a side view of a second rack-mountable device 740. The device 740 is in a folded open configuration and is positioned in a “slided out” configuration while still remaining attached to the rack 700. Since the device 740 is folded open the top portion 750 is folded up away from the bottom portion 760. The device 710 and the device 740 illustrate two possible positions for a rack-mountable device in the rack 700.

To the extent that the term “includes” or “including” is employed in the detailed description or the claims, it is intended to be inclusive in a manner similar to the term “comprising” as that term is interpreted when employed as a transitional word in a claim. Furthermore, to the extent that the term “or” is employed in the detailed description or claims (e.g., A or B) it is intended to mean “A or B or both”. The term “and/or” is used in the same manner, meaning “A or B or both”. When the applicants intend to indicate “only A or B but not both” then the term “only A or B but not both” will be employed. Thus, use of the term “or” herein is the inclusive, and not the exclusive use. See, Bryan A. Garner, A Dictionary of Modern Legal Usage 624 (2d. Ed. 1995).

To the extent that the phrase “one or more of, A, B, and C” is employed herein, (e.g., a data store configured to store one or more of, A, B, and C) it is intended to convey the set of possibilities A, B, C, AB, AC, BC, and/or ABC (e.g., the data store may store only A, only B, only C, A&B, A&C, B&C, and/or A&B&C). It is not intended to require one of A, one of B, and one of C. When the applicants intend to indicate “at least one of A, at least one of B, and at least one of C”, then the phrasing “at least one of A, at least one of B, and at least one of C” will be employed.

What is claimed is:

1. A device, comprising:
a display having a corner to diagonally opposite corner dimension of at least seventeen inches;
a pointing apparatus having at least three buttons;
a communication access port positioned on the front of the device; and
an identification light positioned on the front of the device, the identification light being configured to take on at least two states;
the device being configured to fold open and to fold shut, and when folded shut, to fit into a 1.75 inch high rack space in a rack, the front of the device being visible when the device is mated to the rack.

2. The device of claim 1, the device being configured to be able to be folded open while mated to the rack.

3. The device of claim 1, the device having at least one hinge to foldably connect a first portion of the device and a second portion of the device, the hinge being positioned substantially at the rear of the first portion of the device and substantially at the rear of the second portion of the device.

4. The device of claim 1, the communication access port being a universal serial bus (USB) port.

5. The device of claim 1, including a QWERTY keyboard having a horizontal dimension of at least 14.25 inches measured from the center of a leftmost key on the QWERTY keyboard to the center of a rightmost key on the QWERTY keyboard.

6. The device of claim 1, including
a QWERTY keyboard; and
at least one hinge to foldably connect a first portion of the device and a second portion of the device, the hinge being positioned substantially at the rear of the first portion of the device and substantially at the rear of the second portion of the device;
the device being configured to fold open while mated to the rack;
the identification light being selectively controllable to take on two states, the two states facilitating locating the device in a rack;
the communication access port being a universal serial bus (USB) port;
the rack being a nineteen inch rack.

7. A device, comprising:
a display apparatus having a corner to diagonally opposite corner dimension larger than fifteen inches;
a keyboard having a horizontal dimension larger than twelve inches;
a visual selection and control unit having more than two buttons;
a communication connector positioned to be accessible from the front of the device when the device is located in a rack; and
a light display positioned to produce a visible light that is viewable from the front of the device when the device is located in a rack;
the device being configured with at least two portions hinged together;
the device being configured to fit when folded into a 1 U space in a rack.

8. The device of claim 7, the display apparatus having a corner to diagonally opposite corner dimension of at least seventeen inches.

9. The device of claim 8, the visual selection and control unit being a touch pad having three buttons.

10. The device of claim 9, the communication connector being a universal serial bus (USB) port.

11. The device of claim 10, the light display being selectively controllable to facilitate locating the device when the device is positioned in a rack.

12. The device of claim 11, including a connector to connect the device to a cooling fluid conveyor, the connector being positioned on the front of the device when the device is positioned in a 1 U space.

13. The device of claim 12, the device being configured to slide forward and backward in a rack space and to fold open while mated to the rack.

14. The device of claim 7,
the display apparatus having a corner to diagonally opposite corner dimension of at least seventeen inches.
the visual selection and control unit being a touch pad having three buttons;
the communication connector being a universal serial bus (USB) port;
the light display being selectively controllable to indicate two or more states;
the device being configured to be folded open and shut;
the device being configured to slide forward and backward in the rack space and to fold open without being physically separated from the rack;
the keyboard being a QWERTY keyboard having a horizontal dimension of at least twelve inches; and
the rack being a nineteen inch rack.

15. A method performable in a rack-mountable device comprising an identification light positioned to be viewable from in front of the rack-mountable device, the method comprising:
controlling the light to display a desired signal to facilitate locating the rack-mountable device while the rack-mountable device is positioned in a rack.

16. The method of claim 15, where controlling the light includes:
determining a light pattern different from a light pattern being displayed by another device located in the rack, and
controlling the light to display the light pattern.

17. The method of claim 15, where controlling the light includes displaying a repeating set of signals.

18. The method of claim 17, where the repeating set of signals indicate one of, an error condition, a status, and a device location.

19. The method of claim 15, the rack-mountable device comprising:
a display having a corner to diagonally opposite corner dimension of at least seventeen inches;
a pointing apparatus having at least three buttons; and
a communication access port positioned on the front of the device;
the device being configured to fold open and to fold shut, and when folded shut, to fit into a 1.75 inch high rack space with the front of the device being visible when the device is mated to the rack.

20. A computer-readable medium storing processor executable instructions that when executed by a machine cause the machine to perform a method, the method comprising:
controlling a light positioned to be viewable from in front of a rack-mountable device while the rack-mountable device is positioned in a rack, the light being controllable to display a desired signal to facilitate locating the rack-mountable device while the rack-mountable device is positioned in a rack.
